(19) United States
(12) Patent Application Publication
(10) Pub. No.: US 2003/0085735 A1
(43) Pub. Date: May 8, 2003

(54) HIGH IMPEDANCE CIRCUIT WITH ACKNOWLEDGE

(76) Inventor: Michael S. Hagedorn, Orlando, FL (US)

Correspondence Address: STEPTOE & JOHNSON LLP, Attn: Stuart T.F. Huang, 1330 Connecticut Ave., NW, Washington, DC, 20036, US

(21) Appl. No.: 09/985,932

(22) Filed: Nov. 6, 2001

(51) Int. Cl. H03K 19/02

(52) U.S. Cl. 326/56

(57) ABSTRACT

A high impedance acknowledge circuit configured to generate an acknowledge signal is provided. An input circuit is configured to receive an input signal and an enable signal. An output circuit is configured to receive a plurality of intermediate signals from the input circuit, generate an output corresponding to the input signal when the output circuit is in an enabled state, and assume a high impedance state when the output circuit is in a disabled state. An acknowledge circuit is configured to receive as an input at least two of the intermediate signals, and to generate the acknowledge signal based on at least the enable signal.

### BACKGROUND OF THE INVENTION

1. Field of the Invention

The present invention relates to a high impedance circuit with acknowledge. More particularly, the present invention relates to a high impedance circuit with acknowledge suitable for use in delay-insensitive asynchronous circuits.

2. Discussion of Background Information

a. Asynchronous Circuits

Asynchronous circuits have been proposed that are intended to operate without a clock. One asynchronous logic paradigm is disclosed in U.S. Pat. No. 5,305,463 (“the '463 logic system”), issued Apr. 19, 1994, which is incorporated herein by reference in its entirety. Several data representations are discussed, but in one representation a signal may assume a DATA value or a NULL value. A DATA value, for example, might be a numeric value ZERO or ONE, a logic value TRUE or FALSE, or another meaning not related to binary or Boolean logic representations.

In such a representation, a signal may take the form of two signal lines, with a first signal line designated to mean ZERO or FALSE, and a second signal line designated to mean ONE or TRUE. Each line may assume one of two states: “ASSERTED” or “NULL.” The meaning of a pair of signal lines is determined by the states of the lines. A pair of lines together represents a single binary variable (such as a single bit of binary data) and has four possible states: (1) ASSERTED, ASSERTED, (2) ASSERTED, NULL, (3) NULL, ASSERTED, and (4) NULL, NULL.

The first state (ASSERTED/ASSERTED) is not permitted. The second state (NULL/ASSERTED) represents/signifies meaningful data of a value ZERO or FALSE. The third state (ASSERTED/NULL) represents/signifies meaningful data of value ONE or TRUE. The fourth state (NULL/NULL) can be thought of as indicating that the variable is in a NULL state and has not assumed a meaningful value.

This representation is known as a multi-rail representation of mutually exclusive assertion groups for asynchronous circuits. Dual-rail representation (i.e., two signal lines with three states: NULL, DATA ZERO and DATA ONE) is a specific subset of multi-rail representation. As used herein, DATA collectively refers to DATA ZERO and DATA ONE states for a dual-rail representation (and for any other DATA X states for multi-rail lines with three or more signal lines).

Asynchronous circuits designed consistent with the above require some type of indication that the computations are complete. In asynchronous circuits, this is done through an acknowledge signal which a circuit element sends to an upstream circuit element. The acknowledge signal represents that the circuit has completed processing the last wave of NULL or DATA, and is ready to receive the next wave.

b. Circuits with High Impedance Output States

There are several known circuits that experience high impedance output states in response to particular states of inputs. One such circuit is a tristate buffer, which is a preferred but non-limiting environment in which the present invention may be applied.

FIGS. 1 and 2 show the symbol and logical functionality of a tristate buffer with an active low enable and active high enable, respectively. The general functionality (independent of positive or negative logic) of a tristate buffer is: (1) when the buffer is disabled, the output (Za) is in a high impedance state, and (2) when the buffer is enabled, the output (Za) matches the logical level (H/L) on the input (A).

There are many different designs for tristate output buffers. FIG. 3 illustrates a negative logic adaptation of a tristate buffer 100 with an active low enable found in “Application-Specific Integrated Circuits” by Michael John Sebastian Smith, Addison Wesley, 1997 on page 100. The buffer 100 includes an input stage 102 and an output stage 104. Input stage 102 includes a NAND gate 106, a NOR gate 108, and an inverter 110. The output stage includes a PMOS 112 and an NMOS 114. PMOS 112 receives the output of NAND gate 106, while NMOS 114 receives the output of NOR gate 108. The input stage receives a signal A and an enable signal EN, and the output state outputs a signal ZA. FIG. 4 shows a similar design for an active high enable buffer as shown in FIG. 2. In FIGS. 3 and 4, the relative orientation of the inventor 110 determines the activity level of the enable signal.

FIGS. 5 and 6 are CMOS implementations of the circuits shown in FIGS. 3 and 4, respectively.

In systems that employ a traditional tristate buffer, designers must rely on timing relationships between various signals to ensure that only one tristate buffer can drive a bus line at a time. If multiple drivers are active for a given line, they could conflict. This would cause the data to be undetermined and generate a high current situation on the chip. Since this type of traditional tristate buffer cannot signal or otherwise indicate that it has performed its task, it cannot operate in the normal communication protocol of many asynchronous circuits.

### SUMMARY OF THE INVENTION

The present invention provides a circuit with a high impedance state that is capable of generating an acknowledge signal.

According to an embodiment of the invention, a circuit configured to generate an acknowledge signal is provided. An input circuit is configured to receive an input signal and an enable signal. An output circuit is configured to receive a plurality of intermediate signals from the input circuit, generate an output corresponding to the input signal when the output circuit is in an enabled state, and assume a high impedance state when the output circuit is in a disabled state. An acknowledge circuit configured to receive as an input at least two of the intermediate signals, and to generate the acknowledge signal based on at least the enable signal.

The above embodiment includes various features. The acknowledge circuit preferably includes at least two transistors, and particularly at least four transistors. Two of the at least four transistors are preferably configured to form an inverter.

A preferable combination of features for the above embodiment is as follows. The output circuit includes first and second transistors, and the acknowledge circuit includes a PMOS transistor and an NMOS transistor. The PMOS transistor has a drain connected to an input to the first transistor, and a gate connected to an input of the second transistor. The NMOS has a drain connected to a voltage potential, a gate connected to the input of the second transistor, and a source connected to a source of the PMOS transistor. An input of the inverter is connected to the source of the PMOS, and an output of the inverter is the output of the acknowledge circuit.

Another preferable combination of optional features of the above embodiment is as follows. The output circuit includes two transistors. The output of the acknowledge signal is configured to assume a first state when the output circuit is in the enabled state, and a second state when the output circuit is in the high impedance state. The output of the acknowledge signal will not transition from the first state to the second state until the output circuit transitions from the enabled state to the high impedance state.

Still another preferable combination of optional features of the above embodiment is as follows. The output circuit includes two transistors. The output of the acknowledge signal is configured to assume a first state when one of the two transistors is ON, and a second state when both of the transistors are OFF. The output of the acknowledge signal will not transition from the first state to the second state until the two transistors are OFF.

According to another embodiment of the invention, a high impedance with acknowledge circuit operable within a multi-rail asynchronous circuit is provided. An input circuit is configured to receive a single rail input signal and a single rail enable signal. An output circuit includes first and second transistors, a gate of the first transistor receiving a first signal from the input circuit and a gate of the second transistor receiving a second signal from the input circuit. The output circuit is configured to generate a single rail output signal corresponding to the input signal when the output circuit is in an enabled state, and assume a high impedance state when the output circuit is in a disabled state. An acknowledge circuit is configured to receive as an input the first and second signals, and to generate an acknowledge signal based on the enable signal.

The above embodiment includes various features. The acknowledge circuit preferably includes at least two transistors, and particularly at least four transistors. Two of the at least four transistors are preferably configured to form an inverter.

A preferable combination of features for the above embodiment is as follows. The acknowledge circuit includes a PMOS transistor and an NMOS transistor. The PMOS transistor has a drain connected the gate of the first transistor, and a gate connected to the gate of the second transistor. The NMOS transistor has a drain connected to a voltage potential, a gate connected to the gate of the second transistor, and a source connected to a source of the PMOS transistor. An input of the inverter is connected to the source of the PMOS, and an output of the inverter is the output of the acknowledge circuit.

Another preferable combination of optional features of the above embodiment is as follows. The output circuit includes two transistors. The output of the acknowledge circuit is configured to assume a first state when one of the two transistors is ON, and a second state when both of the transistors are OFF. The output of the acknowledge signal will not transition from the first state to the second state until the two transistors are OFF.

Preferably, the first and second transistors of the above embodiment are configured in series between two different voltage potentials, configured as a pass gate.

According to another embodiment of the above invention, a tristate buffer configured to generate an acknowledge signal is provided. An input circuit is configured to receive an input signal to and an enable signal. An output circuit is configured to receive a plurality of intermediate signals from the input circuit, generate an output corresponding to the input signal when the output circuit is in an enabled state, and assume a high impedance state when the output circuit is in a disabled state. An acknowledge circuit is configured to receive as an input at least two of the intermediate signals, and to generate an output that is opposite of the enable signal. The acknowledge circuit includes a PMOS transistor and an NMOS transistor. The PMOS transistor has a drain configured to receive one of the intermediate signals, and a gate connected to an output of the NOR gate. The NMOS transistor has a drain connected to a voltage potential, a gate configured to receive another of the intermediate signals, and a source connected to a source of the PMOS transistor. An input of an inverter is connected to the source of the PMOS, and an output of the inverter is a basis of the output of the acknowledge circuit.

Other exemplary embodiments and advantages of the present invention may be ascertained by reviewing the present disclosure and the accompanying drawings.

### BRIEF DESCRIPTION OF THE DRAWINGS

The present invention is further described in the detailed description which follows, in reference to the noted plurality of drawings by way of non-limiting examples of certain embodiments of the present invention, in which like numerals represent like elements throughout the several views of the drawings, and wherein:

FIG. 1 shows the symbol and logic functionality of a tristate buffer with an active low enable.

FIG. 2 shows the symbol and logic functionality of a tristate buffer with an active high enable.

FIG. 3 shows a schematic of a tristate buffer with an active low enable according to the prior art.

FIG. 4 shows a schematic of a tristate buffer with an active high enable according to the prior art.

FIG. 5 shows a CMOS implementation of the schematic of FIG. 3.

FIG. 6 shows a CMOS implementation of the schematic of FIG. 4.

FIG. 7 shows a preferred embodiment of the present invention in conjunction with the schematic implementation of FIG. 5.

FIG. 8 shows a preferred embodiment of the present invention in conjunction with the schematic implementation of FIG. 6.

FIGS. 9-14 show non-limiting examples of output stage implementations that can operate with the present invention.

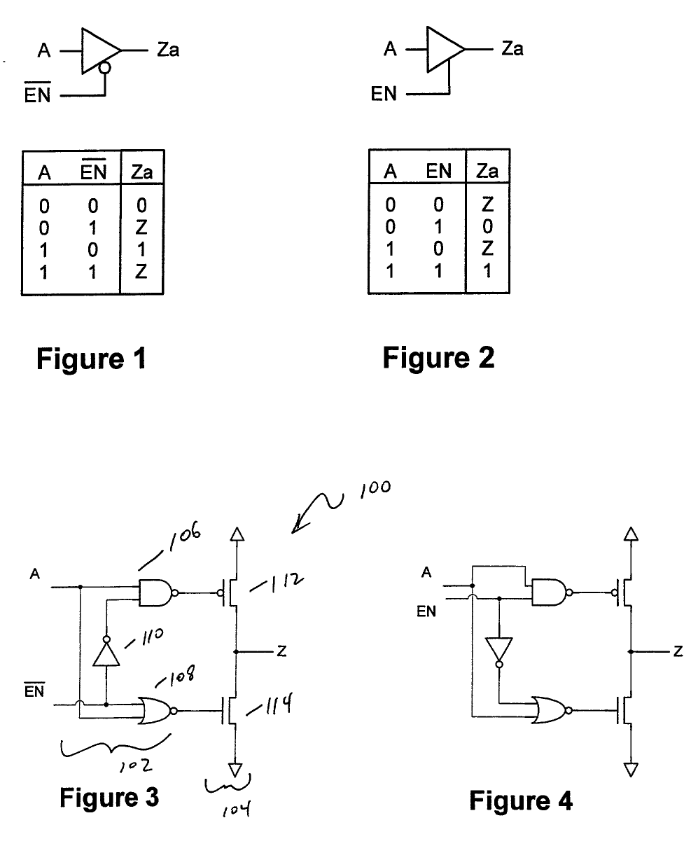

### DETAILED DESCRIPTION OF THE EXEMPLARY EMBODIMENT

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

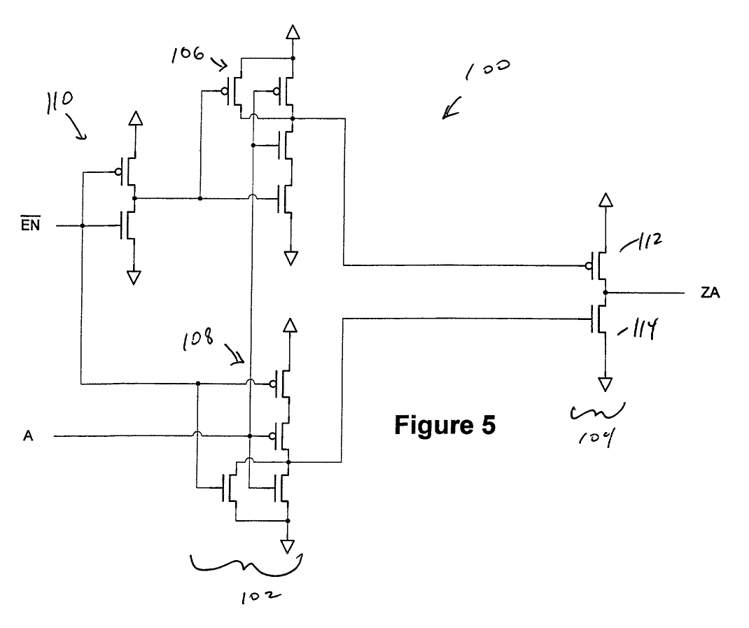

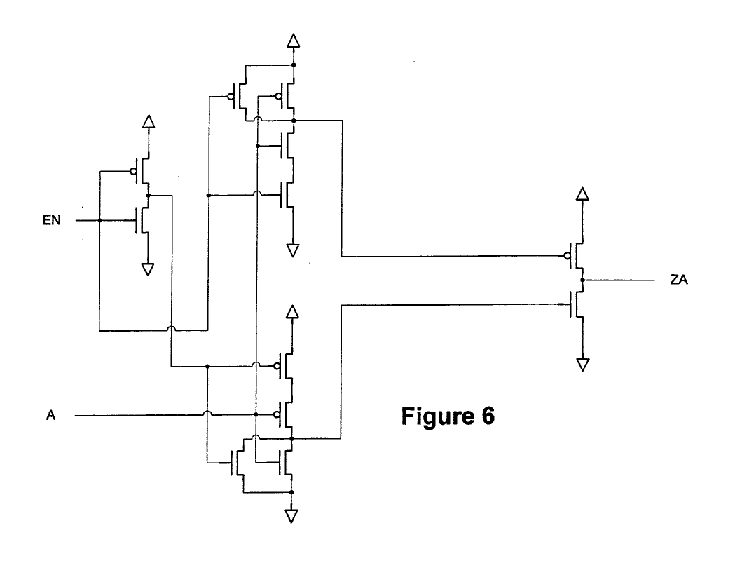

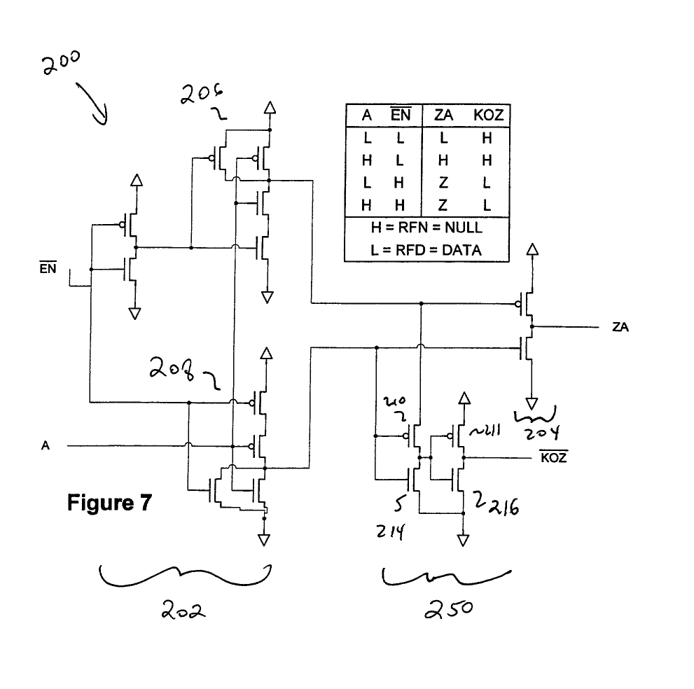

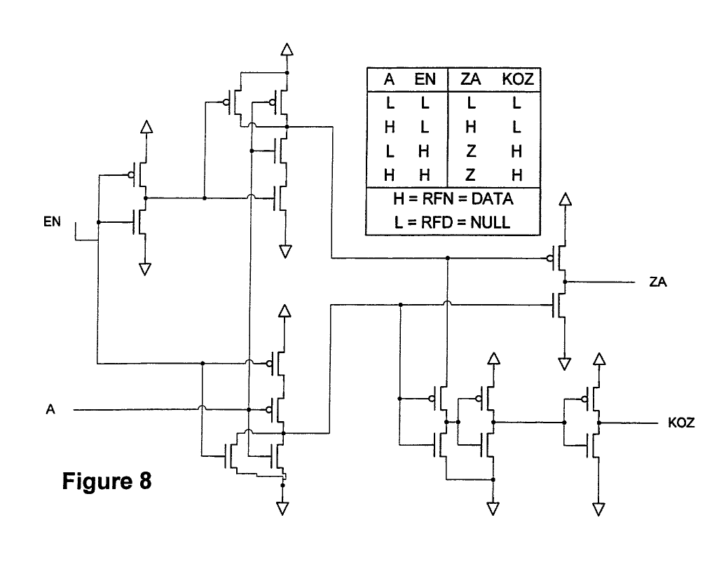

FIG. 7 illustrates a preferred embodiment of the invention in a tristate buffer 200 with active low enable. Tristate buffer 200 includes the circuit elements of the traditional tristate buffer shown in FIGS. 3 and 5, including input stage 202 and output stage 204. This embodiment includes an acknowledge circuit 200 that connects between input stage 202 and 204. Acknowledge circuit 200 includes PMOS 210 and 212, and NMOS 214 and 216.

The drain of PMOS 210 connects to the input of the gate of PMOS 112, while the gates of both PMOS 210 and NMOS 214 connect to the input to the gate of NMOS 114. PMOS 212 and NMOS 216 are configured as an inverter that connects to the source connection of PMOS 210 and NMOS 214. The inverter generates an output KOZ, which represents an acknowledgment signal for enable signal EN. The presence of the inverter is not a strict requirement, but it makes the implementation more robust and consistent by providing a degree of isolation from external circuit elements.

When EN represents DATA (LOW), it enables buffer 200 and generates a ZA consistent with the input A. Regardless of the state of A, KOZ will be NULL (HIGH). This represents a request for NULL on the associated inputs.

When EN represents NULL (HIGH), it turns both transistors in the output stage OFF, such that the output of buffer 200 is in a high impedance state. The resulting HIGH output of NAND gate 206 and LOW output of the NOR gate 208 generate a KOZ of NULL (HIGH). This represents a request for DATA on the associated input. The transistor implementation is such that KOZ will not transition to DATA until after the output transistors have both been turned OFF.

The present invention may also be used in a positive logic tristate buffer. In such an embodiment, an additional inverter is added to the output of the acknowledge circuit 200 to provide an appropriate KOZ. In the alternative, the inverter inside acknowledge circuit 200 may be removed, although the isolation properties of an inverter render this a non-optimal, albeit viable, solution.

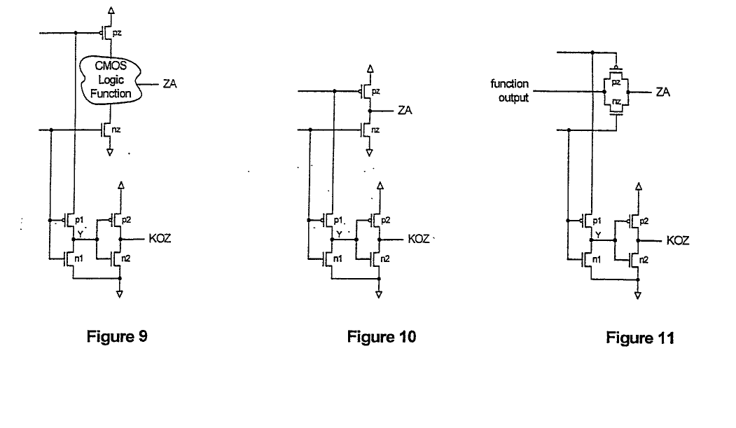

As noted above, the use of the present invention in a tristate buffer is but one example of its application. Any circuit that terminates in a similar arrangement where the output is cut off from Vdd and Vss by two transistors to establish a high impedance output may be used. FIGS. 9-11 show examples of various output stage implementations that the present invention may operate with. In each case, turning the two transistors OFF places the output in a high impedance state. In these examples, the PMOS transistor is OFF when driven to Vdd, and the NMOS transistor is OFF when driven to Vss. The present invention can detect the resulting high impedance state by detecting when both transistors are OFF.

In FIG. 9, isolating the logic function from both Vdd and Vss places ZA into the high impedance. In FIG. 10, the output stage (pz, nz) is driven so that ZA is connected to only one power rail (Vdd or Vss) to output a data value or ZA is disconnected from both power rails to put it into the high impedance state. In FIG. 11, transistor pair pz, nz are used in a pass gate configuration. If both transistors are turned OFF, ZA exhibits high impedance. If both transistors are turned on, ZA is connected to the function output and will exhibit the same signal level as the function output.

In these examples, When pz and nz are both off, the gate of pz is at Vdd and so is the drain of p1. The gate of nz is at Vss and so is the input of the inverter made by p1 and n1. Since the input of the p1/n1 inverter is Vss (LOW), its output Y will be Vdd(p1), which is HIGH. Output KOZ will thus be low when output ZA is in the high impedance state. When nz is ON, n1 is ON and Y is pulled down to Vss(n1) or LOW. Consequently, output KOZ will be HIGH. The state of pz (ON/OFF) is not relevant. When pz is ON, the drain of p1 is at Vss. If nz is OFF, n1 is OFF and p1 is ON, connecting Y to Vss (LOW) through the drain of p1. Consequently, output KOZ will be high.

If output ZA is in the high impedance state, output KOZ will be low. Any other condition on output ZA will cause output KOZ to be high. In asynchronous logic, if output KOZ is used to acknowledge input EN, the activity level of KOZ is preferably the opposite that of EN. For example, if EN=HIGH places output ZA in the high impedance state, KOZ=LOW should be used to signal that the output ZA is in the high impedance state. Positive or negative logic implementations of the circuit preferably operate the same way, in that the only difference is the preferably activity level of the signals. The activity levels are set by inverting the EN input or KOZ output.

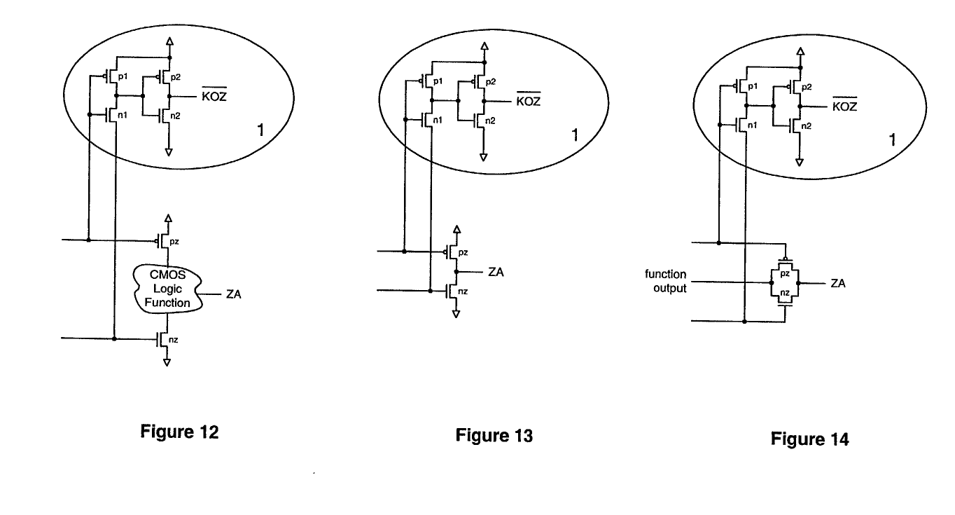

FIGS. 12-14 show other configurations of the acknowledge circuit in which KOZ is high when the output is a high impedance.

When used in conjunction with multi-rail logic, preferably one tristate buffer is used for each rail, such that the signal A input represents a single rail of the multi-rail signal. The enable signal EN is thus preferably a single rail acknowledge signal from another circuit.

Applicant notes that “high impedance” is a technical phrase that is recognized in the art of electronics as a state of operation when dealing with transistors, similar to ON or OFF. The recitation of “high” is not meant to include or imply any numerical value.

It is noted that the foregoing examples have been provided merely for the purpose of explanation and are in no way to be construed as limiting of the present invention. While the present invention has been described with reference to certain embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed is:

1. A circuit configured to generate an acknowledge signal, comprising:
an input circuit configured to receive an input signal and an enable signal;
an output circuit configured to:
receive a plurality of intermediate signals from said input circuit;
generate an output corresponding to said input signal when said output circuit is in an enabled state; and
assume a high impedance state when said output circuit is in a disabled state; and
an acknowledge circuit configured to receive as an input at least two of said intermediate signals, and to generate said acknowledge signal based on at least said enable signal.

2. The circuit of claim 1, wherein said acknowledge circuit includes at least two transistors.

3. The circuit of claim 1, wherein said acknowledge circuit includes at least four transistors;

4. The circuit claim 3, wherein two of said at least four transistors are configured to form an inverter.

5. The circuit of claim 4, further comprising:
said output circuit including first and second transistors;
said acknowledge circuit including a PMOS transistor and an NMOS transistor;
said PMOS transistor having a drain connected to an input of said first transistor, and a gate connected to an input of said second transistor; and
said NMOS having a drain connected to a voltage potential, a gate connected to said input of said second transistor, and a source connected to a source of said PMOS transistor.

6. The circuit of claim 5, wherein an input of said inverter is connected to said source of said PMOS, and an output of said inverter is connected to said output of said acknowledge circuit.

7. The circuit of claim 1, further comprising:
said output circuit including two transistors; and
said output of said acknowledge signal being configured to assume a first state when said output circuit is in said enabled state, and a second state when said output circuit is in said high impedance state;
wherein said output of said acknowledge signal will not transition from said first state to said second state until said output circuit transitions from said enabled state to said high impedance state.

8. The circuit of claim 1, further comprising:
said output circuit including two transistors; and
said output of said acknowledge signal being configured to assume a first state when one of said two transistors is ON, and a second state when both of said transistors are OFF;
wherein said output of said acknowledge signal will not transition from said first state to said second state until said two transistors are OFF.

9. The tristate buffer of claim 4, further comprising:
said input circuit including a NAND gate and a NOR gate;
said acknowledge circuit including a PMOS transistor and an NMOS transistor;
said NMOS transistor having a source connected to an output of said NOR gate, and a gate connected to an output of said NAND gate; and
said PMOS having a source connected to a voltage potential, a gate connected to an output of said NAND gate, and a drain connected to a drain of said PMOS transistor.

10. The tristate buffer of claim 9, wherein an input of said inverter is connected to said drain of said PMOS, and an output of said inverter is said output of said acknowledge circuit.

11. A high impedance with acknowledge circuit operable within a multi-rail asynchronous circuit, comprising:
an input circuit configured to receive a single rail input signal and a single rail enable signal;
an output circuit including first and second transistors, a gate of said first transistor receiving a first signal from said input circuit and a gate of said second transistor receiving a second signal from said input circuit;
said output circuit being configured to generate a single rail output signal corresponding to said input signal when said output circuit is in an enabled state, and assume a high impedance state when said output circuit is in a disabled state; and
an acknowledge circuit configured to receive as an input said first and second signals, and to generate an acknowledge signal based on said enable signal.

12. The circuit of claim 11, wherein said acknowledge circuit includes at least two transistors.

13. The circuit of claim 11, wherein said acknowledge circuit includes at least four transistors;

14. The circuit of claim 11, wherein two of said at least four transistors are configured to form an inverter.

15. The circuit of claim 14, further comprising:
said acknowledge circuit including a PMOS transistor and an NMOS transistor;
said PMOS transistor having a drain connected said gate of said first transistor, and a gate connected to said gate of said second transistor; and
said NMOS transistor having a drain connected to a voltage potential, a gate connected to said gate of said second transistor, and a source connected to a source of said PMOS transistor.

16. The tristate buffer of claim 15, wherein an input of said inverter is connected to said source of said PMOS, and an output of said inverter is said output of said acknowledge circuit.

17. The tristate buffer of claim 1 1, further comprising:
said output circuit including two transistors; and
said output of said acknowledge signal being configured to assume a first state when one of said two transistors is ON, and a second state when both of said transistors are OFF;
wherein said output of said acknowledge signal will not transition from said first state to said second state until said two transistors are OFF.

18. The circuit of claim 1 1, wherein said first and second transistors are configured in series between two different voltage potentials.

19. The circuit of claim 11, wherein said first and second transistors are configured as a pass gate.

20. The tristate buffer of claim 11, further comprising:
said input circuit including a NAND gate and a NOR gate;
said acknowledge circuit including a PMOS transistor and an NMOS transistor;
said NMOS transistor having a source connected to an output of said NOR gate, and a gate connected to an output of said NAND gate; and
said PMOS having a source connected to a voltage potential, a gate connected to an output of said NAND gate, and a drain connected to a drain of said PMOS transistor.

21. The tristate buffer of claim 20, wherein an input of said inverter is connected to said drain of said PMOS, and an output of said inverter is said output of said acknowledge circuit.

22. A tristate buffer configured to generate an acknowledge signal, comprising:
an input circuit configured to receive an input signal to and an enable signal;
an output circuit configured to:
receive a plurality of intermediate signals from said input circuit;
generate an output corresponding to said input signal when said output circuit is in an enabled state; and
assume a high impedance state when said output circuit is in a disabled state; and
an acknowledge circuit configured to receive as an input at least two of said intermediate signals, and to generate an output that is opposite of said enable signal, said acknowledge circuit comprising:
a PMOS transistor and an NMOS transistor,
said PMOS transistor having a drain configured to receive one of said intermediate signals, and a gate connected to an output of said NOR gate;
said NMOS transistor having a drain connected to a voltage potential, a gate configured to receive another of said intermediate signals, and a source connected to a source of said PMOS transistor; and
an input of an inverter is connected to said source of said PMOS, and an output of said inverter is a basis of said output of said acknowledge circuit.

23. A tristate buffer configured to generate an acknowledge signal, comprising:
an input circuit configured to receive an input signal to and an enable signal;
an output circuit configured to:
receive a plurality of intermediate signals from said input portion;
generate an output corresponding to said input signal when said output circuit is in an enabled state; and
assume a high impedance state when the output circuit is in a disabled state; and
an acknowledge circuit configured to receive as an input at least two of said intermediate signals, and to generate an output that is the opposite of said enable signal, said acknowledge circuit comprising:
a PMOS transistor and an NMOS transistor,;
said NMOS transistor having a source configured to receive one of said intermediate signals, and a gate connected to an output of said NAND gate;
said PMOS transistor having a source connected to a voltage potential, a gate configured to receive another of said intermediate signals, and a drain connected to a source of said PMOS transistor; and
an input of an inverter is connected to said drain of said PMOS, and an output of said inverter is said output of said acknowledge circuit.
